(19) United States
(12) Patent Application Publication
(10) Pub. No.: US 2026/0059846 A1
(43) Pub. Date: Feb. 26, 2026

(54) INTEGRATING CAPACITOR INTO DRIVE TRANSISTOR BY EXTENDING SOURCE UNDER GATE FOR MICRO-DISPLAY SUB-PIXELS

(71) Applicant: Meta Platforms Technologies, LLC, Menlo Park, CA (US)

(72) Inventors: Gang Chen, San Jose, CA (US); Qianqian Wang, Santa Clara, CA (US); Wonjae Choi, San Jose, CA (US); Min Hyuk Choi, San Jose, CA (US)

(21) Appl. No.: 18/815,664

(22) Filed: Aug. 26, 2024

(51) Int. Cl. H01L 27/06; H01L 21/265; H01L 29/66; H01L 29/78; H01L 29/94

(52) U.S. Cl. CPC H10D 84/811; H01L 21/26513; H10D 1/047; H10D 1/66; H10D 30/022; H10D 30/601

(57) ABSTRACT

A semiconductor device includes a well formed in a semiconductor substrate, the well including a threshold voltage (Vt) implant. A source region and a drain region is created in the well, and a gate contact is formed over an oxide layer. The source region includes a source extension that is extended under a portion of the gate contact to create an integrated capacitor.

### BACKGROUND

### Technical Field

The present disclosure is related generally to micro-displays, and more specifically, to integrating capacitor into drive transistor by extending source under gate for micro-display sub-pixels.

### Related Art

A micro-display is a term used for ultra-high-resolution displays with a dense pixel arrangement, often reaching thousands of pixels per inch (PPI) within a compact size of around one inch. In mixed reality (MR), virtual reality (VR) and augmented reality (AR) device applications, a micro-display is an important component and enabling factor. Silicon backplane makes smaller pitch pixels possible as compared to traditional thin-film transistor (TFT) options. Threshold voltage (Vt) compensation is commonly adopted to prevent variations of the voltage Vt. This results in a uniform and stable display performance.

Vt compensation needs at least one capacitor connecting the gate and source of a driver capacitor to complete the charge dissipation during the compensation. Such capacitors are normally metal-oxide semiconductor (MOS) capacitors, metal-insulator-metal (MIM) capacitors or other kinds of capacitors compatible with complementary-MOS (CMOS) silicon process. The compensating capacitors, either need extra area on the layout, and/or extra process to form the structure. In either case, the pixel pitch of the micro-display or the cost increases.

### SUMMARY

An aspect of the subject technology is directed to a semiconductor device includes a well formed in a semiconductor substrate, the well including a threshold voltage (Vt) implant. A source region and a drain region is created in the well, and a gate contact is formed over an oxide layer. The source region includes a source extension that is extended under a portion of the gate contact to create an integrated capacitor.

Another aspect of the disclosure is related to a method including forming a well in a semiconductor substrate, creating a source region including a source extension in the well, and forming a drain region in the well and a gate contact over an oxide layer so that the source extension is under a portion of the gate contact to create an integrated capacitor.

Yet another aspect of the disclosure is related to a drive transistor including an MOS transistor that includes an extended source region, a drain region and a gate contact. The extended source region is configured to extend under the gate contact to form a compensation capacitor between the gate contact and the extended source region.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram illustrating an example of a headset for MR applications within which a micro-display of the subject technology is implemented.

FIGS. 2A and 2B are schematic diagrams illustrating a traditional drive-transistor circuit and an example of a drive-transistor circuit of the subject technology.

FIG. 3 is a timing diagram illustrating examples of switching pulses associated with switches of FIGS. 2A and 2B, according to some aspects of the subject technology.

FIGS. 4A and 4B are schematic diagrams illustrating an implementation of a traditional drive-transistor circuit and an example implementation of a drive-transistor circuit of the subject technology.

FIGS. 5A, 5B, 5C, 5D and 5E are schematic diagrams illustrating in-process steps of implementing a drive transistor, according to some aspects of the subject technology.

FIG. 6 is a flow diagram illustrating a process for implementing a drive transistor, according to some aspects of the subject technology.

In the figures, elements having the same or similar reference numerals are associated with the same or similar attributes, unless explicitly stated otherwise.

### DETAILED DESCRIPTION

In the following detailed description, numerous specific details are set forth to provide a full understanding of the present disclosure. It will be apparent, however, to one ordinarily skilled in the art, that embodiments of the present disclosure may be practiced without some of these specific details. In other instances, well-known structures and techniques have not been shown in detail so as not to obscure the disclosure. Embodiments as disclosed herein will be described with the description of the attached figures.

According to some aspects, the subject technology is directed to integrating capacitor into drive transistor by extending source under gate for micro-display sub-pixels. In some implementations, the drive transistor is a micro-display drive transistor, but the application of the subject technology is not limited to micro-displays and the disclosed drive circuit can be used for any application that uses a capacitor for Vt compensation. In some implementations, the transistor can be an n-type MOS (nMOS) or a p-type MOS (pMOS) transistor. In some implementations, the subject solution can be applied to a 4T1C compensation pixel circuit schemes, but the application is not limited to the 4T1C scheme and can also be applied to other schemes such as 2T1C, 4T2C, 5T6C and the like.

In some implementations, the subject solution can be implemented for pixels with multiple capacitors, for example, the gate-to-source or gate-to-drain capacitors (e.g., for switch transistors). Compared to using nMOS or double-diffused MOS (DMOS) for compensation capacitor implementation, the method of the subject technology uses less area and routing, produces less parasitic couplings, and possibly results in faster frame rate by using one more mask layer for source extension implant. As compared to MIM capacitors, the benefits of the disclosed solution include less routing, less parasitic couplings, possibly faster frame rate, and less mask layers, which may result in slightly increased pixel size due to slightly larger drive transistor with a small area of source extension.

In general, by integrating the capacitor into the drive transistor, the pixel structure and routing becomes simpler, allowing smaller pixel design, and less processing steps, and potentially resulting in smaller parasitic coupling, higher frame rate, better performance and improved yield.

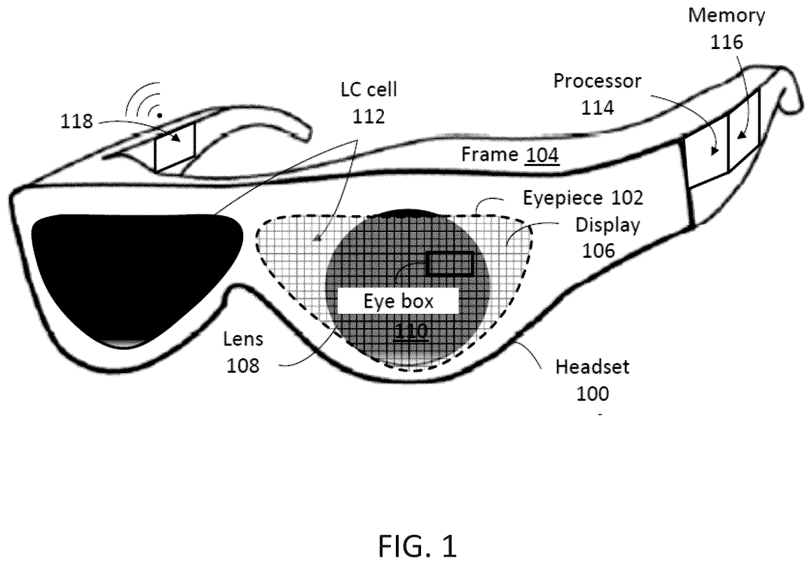

Now turning to the description of figures, FIG. 1 is a schematic diagram illustrating an example of a headset 100 for MR applications within which some aspects of the subject technology are implemented. The eyepieces 102 are mounted on a frame 104 and provide a transmitted image from the real world to a headset user. In some embodiments, a display 106 may also be configured to provide a computer-generated image to the headset user (e.g., for MR applications). In some implementations, the display 106 is a micro-display driven by a drive transistor of the subject technology, in which the compensation capacitor is implemented by an extension of the source area under the gate of the drive transistor. The lens 108 optically couples the display 106 to an eye box 110 delimiting an area where a user's pupil is located.

At least one of the eyepieces 102 or the lens 108 includes an LC cell 112, as disclosed herein. Accordingly, the LC cell 112 may include a liquid crystal layer sandwiched between polymer aligning layers, and electrode layers (not shown here for simplicity). The electrode layers provide an electric field that aligns the LC molecules in the LC layer along the electric field. The polymer alignment layer provides a default alignment of the LC molecules in the LC layer, absent an electric field across the electrode layer. When the electrodes are activated, the polymer alignment layer is oxidized (anode) and reduced (cathode), thus losing its ability to attach with LC molecules of the LC layer, which become free to align with the electric field. An LC layer may be used in one or both eyepieces 102 as a transparency controller. For example, the user may desire a high transparency in an area of an eyepiece that provides a real-world throughput image. When a portion of the eyepiece is used to display a computer-generated image or icon, it is desirable that the background of the eyepiece be opaque. In one or more implementations, the lens 108 coupling the display 106 or eyepiece 102 to the eye box 110 may include a pancake lens or other type of lens.

The headset 100 may include a processor circuit 114 and a memory circuit 116. The memory circuit 116 may store instructions which, when executed by processor circuit 114, cause the headset 100 to provide the computer-generated image. In addition, the headset 100 may include a communications module 118. The communications module 118 may include radio-frequency software and hardware configured to wirelessly communicate with the processor circuit 114 and the memory circuit 116, with a network 120, a remote server 130, a database 140, or a mobile device 150 handled by the user of the headset 100. The headset 100, mobile device 150, remote server 130, and database 140 may exchange commands, instructions, and data, via a dataset 160, through the network 120. Accordingly, the communications module 118 may include radio antennas, transceivers, and sensors, and also digital processing circuits for signal processing according to any one of multiple wireless protocols such as Wi-Fi, Bluetooth, Near field contact (NFC), and the like.

In addition, the communications module 118 may also communicate with other input tools and accessories cooperating with the headset 100 (e.g., handle sticks, joysticks, mouse, wireless pointers, and the like). The network 120 may include, for example, any one or more of a local area network (LAN), a wide area network (WAN), the Internet, and the like. Further, the network 120 can include, but is not limited to, any one or more of the following network topologies, including a bus network, a star network, a ring network, a mesh network, a star-bus network, tree or hierarchical network, and the like.

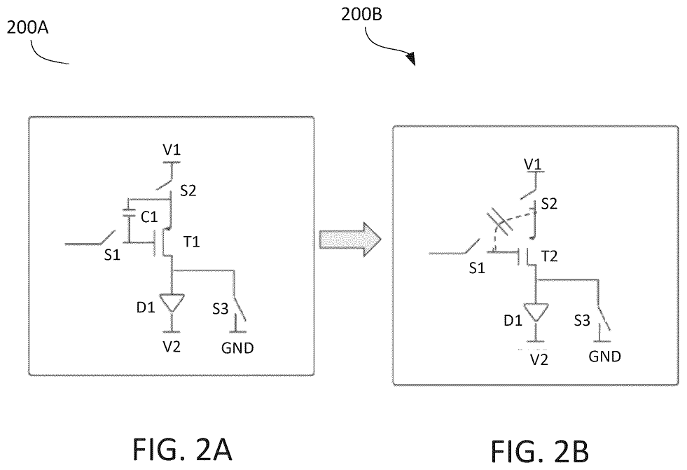

FIGS. 2A and 2B are schematic diagrams illustrating a traditional drive-transistor circuit 200A and an example of a drive-transistor circuit 200B of the subject technology. The traditional drive-transistor circuit 200A includes a transistor (e.g., a pMOS transistor) T1, a diode D1, a compensation capacitor C1 and switches S1, S2 and S3. The compensation capacitor C1 is connected between a gate node and a source node of the transistor T1. Switch S1 is an enable switch and switch S3 is a reset switch. One terminal of the switch S1 is connected to the gate node of the transistor T1. The other terminal of the switch S1 can be connected to an input signal source or to another input circuit. The switch S2 couples the source node of the transistor T1 to a first supply voltage V1 (e.g., an extremely low (LE) VSS). The switch S3 couples the drain node of the transistor T1 to a ground potential (GND). The diode D1 connects the drain node of the transistor T1 to a second supply voltage V2 (e.g., an LEVDD).

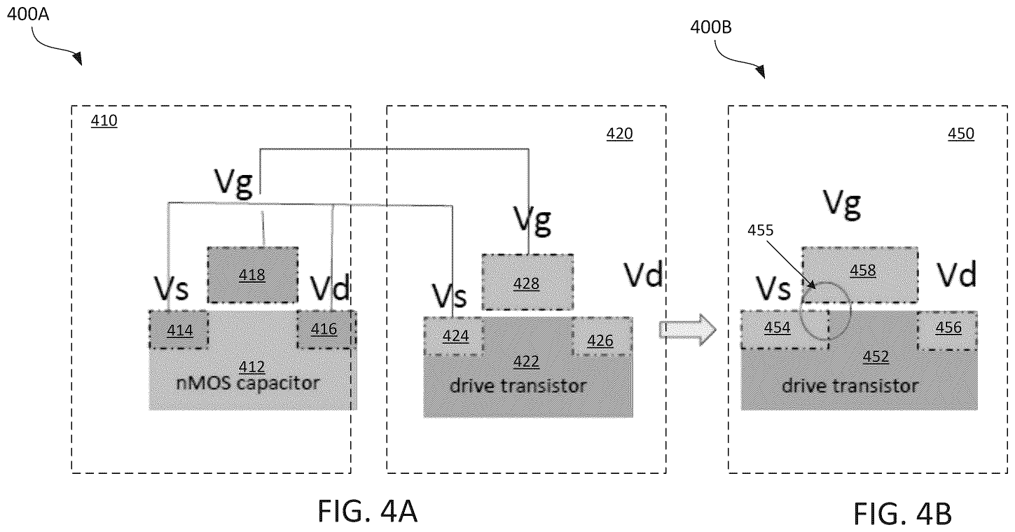

The drive-transistor circuit 200B of the subject technology is similar to the drive transistor circuit 200B except for the compensation capacitor C1, which is replaced by an internal capacitor formed between and extension of the source structure of the transistor T2 under the gate structure of the transistor T2, as shown and described in more details below with respect to FIG. 4B. The integration of the compensation capacitor C1 into the drive transistor T2 results in a simpler pixel structure and routing, allows a smaller pixel design, and less processing steps. The integration also potentially results in smaller parasitic coupling, higher display frame rate, better display performance and improved yield.

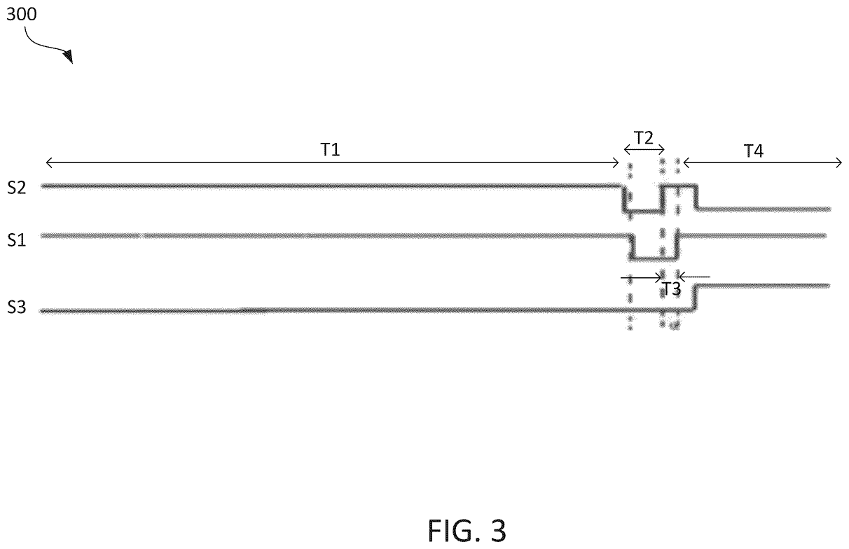

FIG. 3 is a timing diagram 300 illustrating examples of switching pulses associated with switches of FIGS. 2A and 2B, according to some aspects of the subject technology. The timing diagram 300 includes one cycle of switching pulses of the switches S1, S2 and S3 of FIGS. 2A and 2B. during the time T1, which is a data preparation time, switches S1 and S2 are open (OFF) and the switch S3 is closed (ON). This provides a path for a current to flow from the capacitor C1 to the ground through the closed switch S3 to allow discharging of the compensation capacitor C1. During the time T2, which is data writing time, both S1 and S2 are transitioned to ON while S3 is still ON, and the current can flow through the source and drain terminals of the transistor T1. During the time T3, which is an intrinsic self-compensation time, switch S1 opens and switches S2 and S3 are still closed. The time T4 is an emissive time during which switch S2 is open, and switches S1 and S3 toggle.

FIGS. 4A and 4B are schematic diagrams illustrating an implementation 400A of a traditional drive-transistor circuit and an example implementation 400B of a drive-transistor circuit of the subject technology. The implementation 400A shows the structure of the traditional drive-transistor circuit 200A of FIG. 2A and includes structure 410 of the compensation capacitor C1 of FIG. 2A and the structure 420 of the drive transistor T1 of FIG. 2A. The compensation capacitor C1 is implemented by an nMOS transistor including a source region 414 and a drain region 416 formed in an n-type well (n-well) 412 and a gate 418. The source and drain regions 414 and 416 include high-concentration p-type (p+) dopants. The gate 418 is formed on and oxide layer (not shown for simplicity. The capacitance between the gate 418 and the source region 414 works as the compensation capacitor C1.

The structure 420 of the drive transistor T1 is similar to the structure 410 and includes a source region 414 and a drain region 426 formed in an-well 422 and a gate 428, which is similarly formed on an oxide layer. The source region 424 and the gate 428 of the structure 420 are connected, respectively, to the source region 414 and the gate 418 of the structure 410. These connections are similar to the connection of terminal of the compensation capacitor C1 to the gate and source of the drive transistor T1 of FIG. 2A.

The implementation 400B shows the structure of the drive-transistor circuit 200B of FIG. 2B and includes structure 450 of the drive transistor T2 of FIG. 2B with an embedded compensation capacitor. The structure 450 of the drive transistor T2 is similar to the structure 420 of the drive transistor T1 except for a source region 454, which is different from the source region 414. The structure 450 includes the source region 454 and a drain region 456 formed in an n-well 452 and a gate 458, which is similarly formed on an oxide layer. The compensation capacitor C1 is not implemented by a separate structure as done in FIG. 4A, rather, it is implemented by extending the source region 454 under the gate 458. In some implementations, the original width of the source region 454 is within a range of about 200-500 nm, which is extended by about 100 to 300 nm under the gate 458. The extension 455 of the source region 454 and gate 458 function as electrodes and the oxide region under the gate functions as the dielectric of the compensation capacitor. This allows integration of the compensation capacitor into the structure 450 of the drive transistor T2 (of FIG. 2B). The integration removes the need for the separate structure 410 to implement the compensation capacitor C1 and therefore, results in a number of benefits including using less chip area and routing, less parasitic couplings, and faster display frame rate. The cost of having these benefits is using one more mask layers for source extension implant, as described below.

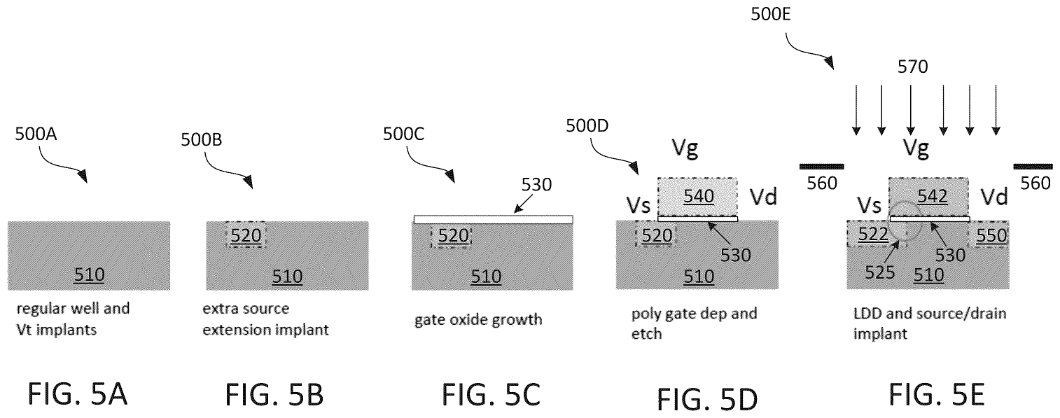

FIGS. 5A, 5B, 5C, 5D and 5E are schematic diagrams illustrating in-process steps 500A, 500B, 500C, 500D and 500E of implementing a drive transistor, according to some aspects of the subject technology. The in-process step 500A includes forming a regular well region (e.g., an n-well) with Vt implants (e.g., with a concentration of 10¹⁵ to 10¹⁶ cm⁻³) on a semiconductor (e.g., silicon) substrate. In practice the substrate would have many well regions for many pixels and what is described here is just one well for a single pixel.

In the in-process step 500B, an extended source region 520, with a width of about 200 to 500 nm, is produced within the n-well region 510 using an ion implantation process.

In the in-process step 500C an oxide (e.g., silicon dioxide) layer 530 is formed over the entire width of the n-well region 510.

In the in-process step 500D, using a mask (not shown for simplicity) a gate contact 540 is formed over the oxide layer 530 by deposition of, for example, a polysilicon layer. The gate contact 540 has an overlap with the source region 520. The width of the overlap can be about 100 to 300 nm. This overlap forms an integrated compensation capacitor that replaces the structure 410 of FIG. 4A, therefore saving a significant chip area, which results in cost saving and better performance of the drive transistor, as described above.

In the in-process step 500E, using a mask 560, an ion implantation process by an ion beam 570 is used to form the drain region 550 and the gate 542. The ion beam 570 would not penetrate the oxide layer but will penetrate the side of the source region 520 to extend its width to form the source region 522.

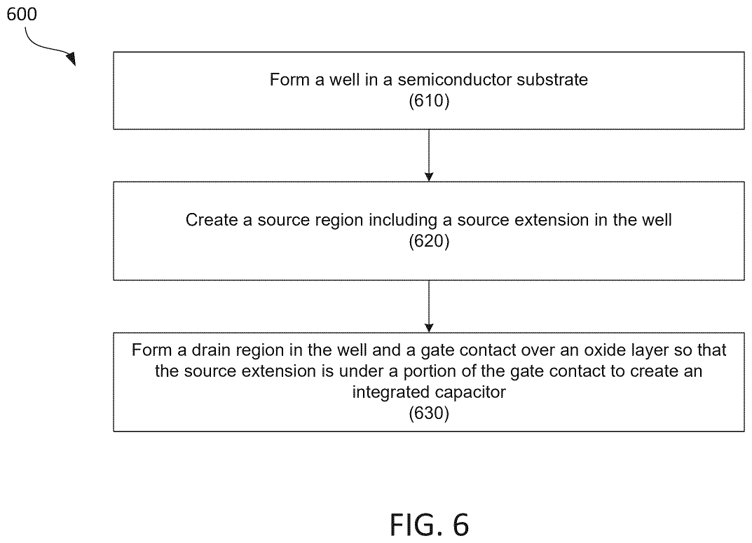

FIG. 6 is a flow diagram illustrating a process 600 for implementing a drive transistor, according to some aspects of the subject technology. In some embodiments, processes consistent with the present disclosure may include at least one or more of the steps in process 600 performed in a different order, simultaneously, quasi-simultaneously, or overlapping in time.

The process 600 includes process steps 610, 620 and 630. In the process step 610, a well is formed in a semiconductor substrate.

In the process step 620, a source region including a source extension is created in the well.

In the process step 630, a drain region is formed in the well and a gate contact is created over an oxide layer so that the source extension is under a portion of the gate contact to create an integrated capacitor.

An aspect of the subject technology is directed to a semiconductor device includes a well formed in a semiconductor substrate, the well including a Vt implant. A source region and a drain region is created in the well, and a gate contact is formed over an oxide layer. The source region includes a source extension that is extended under a portion of the gate contact to create an integrated capacitor.

In some aspects, the well comprises an n-doped well (n-well) and the semiconductor substrate comprises silicon.

In one or more aspects, the source region and the drain region comprise p-doped regions.

In some aspects, the integrated capacitor comprises a compensation capacitor that is configured to compensate for variations of a Vt parameter of a drive metal-oxide-semiconductor (MOS) transistor formed by the source region, the drain region and the gate contact.

In one or more aspects, a width of the source extension is within a range of about 100-300 nm.

In some aspects, the integrated capacitor is configured to replace a separate capacitor implementation using a transistor structure.

In some aspects, the well comprises a p-doped well (p-well) and the source region and the drain region comprise n-doped regions.

In one or more aspects, oxide layer comprise silicon oxide and is formed under the gate contact and over the source extension.

Another aspect of the disclosure is related to a method including forming a well in a semiconductor substrate, creating a source region including a source extension in the well, and forming a drain region in the well and a gate contact over an oxide layer, so that the source extension is under a portion of the gate contact to create an integrated capacitor.

In some aspects, forming the well comprises forming an n-well including Vt implant in a silicon substrate.

In one or more aspects, creating the source region and the drain region comprise forming p-doped regions within the n-well.

In some aspects, receiving a width of the source extension is within a range of about 100-300 nm.

In one or more aspects, the method further comprises forming the oxide layer by forming a silicon oxide before forming the gate contact.

In some aspects, the silicon oxide is formed over the source extension.

In one or more aspects, forming the gate contact comprises depositing a polycrystal layer over the oxide layer.

In some aspects, forming the well comprises forming a p-well including Vt implant in a silicon substrate and creating the source region and the drain region comprise forming n-doped regions within the p-well.

Yet another aspect of the disclosure is related to a drive transistor including an MOS transistor that includes an extended source region, a drain region and a gate contact. The extended source region is configured to extend under the gate contact to form a compensation capacitor between the gate contact and the extended source region.

In some aspects, the extended source region and the drain region are formed by using p-dopant within an n-well including Vt implant created in a silicon substrate.

In one or more aspects, the compensation capacitor is configured to compensate for variation of a Vt parameter of the MOS transistor.

In some aspects, the extended source region and the drain region are formed by using n-dopant within a p-well including Vt implant created in a silicon substrate.

In some aspects, the word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially described as such, one or more features from a described combination can in some cases be excised from the combination, and the described combination may be directed to a sub-combination or variation of a sub-combination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings arc hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples, and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

Aspects of the subject matter described in this disclosure can be implemented to realize one or more of the following potential advantages. The described techniques may be implemented to support a range of benefits and significant advantages of the disclosed eye tracking system. It should be noted that the subject technology enables fabrication of a depth-sensing apparatus that is a fully solid-state device with small size, low power, and low cost.

As used herein, the phrase “at least one of” preceding a series of items, with the terms “and” or “or” to separate any of the items, modifies the list as a whole, rather than each member of the list (i.e., each item).

To the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A semiconductor device, comprising:
a well formed in a semiconductor substrate, the well including a threshold voltage (Vt) implant;
a source region and a drain region created in the well; and
a gate contact formed over an oxide layer,
wherein the source region includes a source extension that is extended under a portion of the gate contact to create an integrated capacitor.

2. The semiconductor device of claim 1, wherein the well comprises an n-doped well (n-well) and the semiconductor substrate comprises silicon.

3. The semiconductor device of claim 1, wherein the source region and the drain region comprise p-doped regions.

4. The semiconductor device of claim 1, wherein the integrated capacitor comprises a compensation capacitor that is configured to compensate for variations of a Vt parameter of a drive metal-oxide-semiconductor (MOS) transistor formed by the source region, the drain region and the gate contact.

5. The semiconductor device of claim 1, wherein a width of the source extension is within a range of about 100-300 nm.

6. The semiconductor device of claim 1, wherein the integrated capacitor is configured to replace a separate capacitor implementation using a transistor structure.

7. The semiconductor device of claim 1, wherein the well comprises a p-doped well (p-well) and the source region and the drain region comprise n-doped regions.

8. The semiconductor device of claim 1, wherein the oxide layer comprise silicon oxide and is formed under the gate contact and over the source extension.

9. A method, comprising:
forming a well in a semiconductor substrate;
creating a source region including a source extension in the well; and
forming a drain region in the well and a gate contact over an oxide layer,
wherein the source extension is formed under a portion of the gate contact to create an integrated capacitor.

10. The method of claim 9, wherein forming the well comprises forming an n-well including Vt implant in a silicon substrate.

11. The method of claim 10, wherein creating the source region and the drain region comprise forming p-doped regions within the n-well.

12. The method of claim 9, wherein a width of the source extension is within a range of about 100-300 nm.

13. The method of claim 9, further comprising forming the oxide layer by forming a silicon oxide before forming the gate contact.

14. The method of claim 13, wherein the silicon oxide is formed over the source extension.

15. The method of claim 9, wherein forming the gate contact comprises depositing a polycrystal layer over the oxide layer.

16. The method of claim 9, wherein forming the well comprises forming a p-well including Vt implant in a silicon substrate and creating the source region and the drain region comprise forming n-doped regions within the p-well.

17. A drive transistor comprising:
an MOS transistor including:
an extended source region, a drain region and a gate contact,
wherein the extended source region is configured to extend under the gate contact to form a compensation capacitor between the gate contact and the extended source region.

18. The drive transistor of claim 17, wherein the extended source region and the drain region are formed by using p-dopant within an n-well including Vt implant created in a silicon substrate.

19. The drive transistor of claim 17, the compensation capacitor is configured to compensate for variation of a Vt parameter of the MOS transistor.

20. The drive transistor of claim 17, wherein the extended source region and the drain region are formed by using n-dopant within a p-well including Vt implant created in a silicon substrate.
